(19) United States
(12) Patent Application Publication
(10) Pub. No.: US 2003/0066975 A1
(43) Pub. Date: Apr. 10, 2003

(54) Systems and methods for reducing contaminants in a charged-particle-beam microlithography system

(75) Inventor: Masashi Okada, Iharaki-ken (JP)

Correspondence Address: KLARQUIST SPARKMAN, LLP, Suite 1600, One World Trade Center, 121 S.W. Salmon Street, Portland, OR, 97204-2988, US

(73) Assignee: Nikon Corporation

(21) Appl. No.: 10/267,222

(22) Filed: Oct. 8, 2002

(30) Foreign Application Priority Data
Oct. 9, 2001 (JP) 2001-310881

(51) Int. Cl. B08B 7/00; H01J 37/317

(52) U.S. Cl. 250/492.2; 134/1

(57) ABSTRACT

Systems and methods are disclosed for reducing contaminants that can accumulate in a charged-particle-beam (CPB) microlithography system during use of the system for CPB microlithography. In general, the disclosed systems utilize a photocatalytic layer disposed on the walls of a vacuum chamber enclosing a CPB optical system of the microlithography system or on the surfaces of one or more components of the CPB optical system in the vacuum chamber. When exposed to a particular radiation, the photocatalytic layer reacts with a reactant, such as water vapor or oxygen, to create hydroxy radicals and/or superoxide ions. The hydroxy radicals and superoxide ions decompose the hydrocarbon-type contaminants and produce volatile reaction products that can be exhausted from the vacuum chamber. The systems and methods improve throughput of the CPB microlithography system because contaminants in the vacuum chamber are decomposed and removed in situ without having to disassemble and clean the microlithography system.

### FIELD

This disclosure pertains to microlithography (projection-transfer of a pattern, defined on a reticle, onto a suitable substrate) and related technologies. Microlithography is a key technology used in the manufacture of microelectronic devices such as integrated circuits, magnetic-recording heads, displays, and micromachines. More specifically, the disclosure pertains to charged-particle-beam (CPB) microlithography and to systems and methods for reducing certain contaminants that accumulate in a vacuum chamber housing certain components of a CPB microlithography system.

### BACKGROUND

As the limitations of optical microlithography have become more apparent, microlithography systems utilizing a charged particle beam (e.g., an electron or ion beam) or an X-ray light source have been developed. These new systems are capable of forming smaller pattern features than conventional optical microlithography systems. Microlithography systems that utilize an electron beam as the lithographic energy beam have the advantage that the electron beam itself can be focused narrowly, thereby resulting in improved pattern-transfer resolution.

A conventional electron-beam microlithography system draws a circuit pattern by narrowly focusing the electron beam, inside a vacuum chamber, on a lithographic substrate coated with a suitable resist and scanning the focused beam across the substrate. This process of using a focused electron beam to draw the pattern line-by-line is time-consuming. Thus, conventional electron-beam drawing systems suffer from extremely low throughput compared to optical microlithography systems that use demagnifying projection-optical systems to transfer entire circuit patterns in one exposure “shot.”

Accordingly, a divided-reticle electron-beam microlithography technique has been developed whereby a pattern is defined on a reticle that is divided into multiple subfields each defining a respective portion of the pattern and being exposed individually. The reticle is positioned in a vacuum chamber and irradiated by an electron beam directed by an illumination-optical system. As the electron beam passes through the irradiated portion of the reticle, the beam acquires an aerial image of the pattern and thus becomes a “patterned beam” propagating downstream of the reticle. The patterned beam then passes through the projection-optical system of the electron beam microlithography system, in which the patterned beam is demagnified and focused onto the surface of a downstream substrate. The area of the substrate that can be exposed with a single exposure shot is relatively large (e.g., 0.25 mm×0.25 mm), resulting in dramatically increased throughput compared to a conventional electron-beam drawing system.

During pattern transfer using any type of CPB microlithography system, however, the charged particle beam may react with certain contaminants inside the vacuum chamber, resulting in decreased accuracy with which the charged particle beam can transfer the pattern. The contaminants may include residual or generated gas (e.g., from the resist, etc.) or any of various substances adsorbed onto the walls of the vacuum chamber or onto the surfaces of optical-system components inside the vacuum chamber. For instance, hydrocarbon-type contaminants may adhere to the inner walls of the vacuum chamber and to components inside the vacuum chamber. These accumulated contaminants may cause localized electrical charge-ups that perturb the trajectory of the charged particle beam in the CPB optical system.

Conventionally, contaminant deposits are removed from the various parts of the vacuum chamber and components therein by disassembling the microlithography system, removing each contaminated component, and individually cleaning the removed component. Because the CPB microlithography system cannot operate while the contaminated components are being cleaned, this conventional cleaning process causes a substantial decrease in the throughput of the system.

### SUMMARY

In view of the shortcomings of the prior art as summarized above, the present disclosure provides, inter alia, systems and methods for reducing contaminants that can accumulate or that have accumulated during charged-particle-beam (CPB) microlithography. In general, the disclosed systems utilize a photocatalytic layer disposed on the walls of the vacuum chamber and/or on the surfaces of components located inside the vacuum chamber. Upon being exposed to certain types of radiation, the photocatalytic layer reacts with a reactant, such as water vapor and/or oxygen, to create hydroxy radicals and/or superoxide ions. Inside the vacuum chamber, hydroxy radicals and superoxide ions decompose hydrocarbon-type contaminants that have accumulated in the vacuum chamber. As a result, the frequency with which components must be removed from the vacuum chamber for cleaning is reduced substantially. Therefore, the throughput of the CPB microlithography system is improved because contaminants in the vacuum chamber can be decomposed in situ and removed without having to disassemble any part of the system.

In a first aspect of the invention, CPB microlithography systems comprising a vacuum chamber and a CPB optical system situated inside the vacuum chamber are provided. In an exemplary embodiment of such a system, a photocatalytic layer is disposed on at least a portion of the inner walls of the vacuum chamber. The photocatalytic layer may comprise, for example, one or more of titanium oxide, zinc oxide, and cadmium sulfide. A radiation source may be situated inside the vacuum chamber and configured to irradiate the photocatalytic layer with, for example, ultraviolet radiation. The system also may include a tank filled with water vapor or oxygen, with a gas-introduction tube fluidly connecting the tank with the interior of the vacuum chamber. Thus, water vapor and/or oxygen may be released into the vacuum chamber during irradiation of the photocatalytic layer in order to generate the hydroxy radicals and/or superoxide ions that decompose hydrocarbon-type contaminants inside the vacuum chamber. The system may further include an exhaust pump and an exhaust tube fluidly connecting the exhaust pump with the vacuum chamber.

In another embodiment of a CPB microlithography system, at least one of the components of the CPB optical system inside the vacuum chamber is coated with the photocatalytic layer. For example, any one of the multiple beam-shaping or beam-focusing components in the illumination-optical system or the projectionoptical system of the CPB optical system may be coated with the photocatalytic layer. Alternatively, at least a portion of the substrate stage of the CPB microlithography system may be coated with the photocatalytic layer.

According to another aspect of the invention, methods are provided for decomposing hydrocarbon-type contaminants in a CPB microlithography system. An embodiment of the method includes coating at least a portion of the inner walls of the vacuum chamber with a photocatalytic layer. As discussed above, the photocatalytic layer may comprise one or more of titanium oxide, zinc oxide, and cadmium sulfide. A reactant, such as water vapor or oxygen, is introduced into the vacuum chamber at appropriate times. The photocatalytic layer is irradiated with radiation, such as ultraviolet (UV) radiation, which causes the photocatalytic layer to react with molecules of the reactant and create hydroxy radicals and/or superoxide ions that decompose the contaminant deposits to volatile reaction products. The method further may include exhausting the volatile reaction products out of the vacuum chamber via an exhaust tube. The method further may include simultaneously irradiating the photocatalytic layer with the charged particle beam used in the CPB microlithography system.

In another embodiment of the method, at least one of the components of the CPB optical system is coated with the photocatalytic layer. Alternatively or in addition, at least a portion of the substrate stage of the CPB microlithography system also may be coated with the photocatalytic layer.

The foregoing and additional features and advantages of the invention will be more readily apparent from the following detailed description, which proceeds with reference to the accompanying drawings.

### BRIEF DESCRIPTION OF THE DRAWINGS

FIG. 1 is an elevational view of a charged-particle-beam (CPB) microlithography system according to a first representative embodiment.

FIG. 2 depicts key reactions of titanium oxide (TiO₂) with gaseous oxygen and water vapor that generate superoxide ions and hydroxy radicals.

### DETAILED DESCRIPTION

The invention is described below in the context of representative embodiments and examples that are not intended to be limiting in any way. Furthermore, the embodiments are described below in the context of use with an electron beam as an exemplary charged particle beam. It will be understood that the general principles disclosed herein are equally applicable to use of an alternative charged particle beam, such as an ion beam.

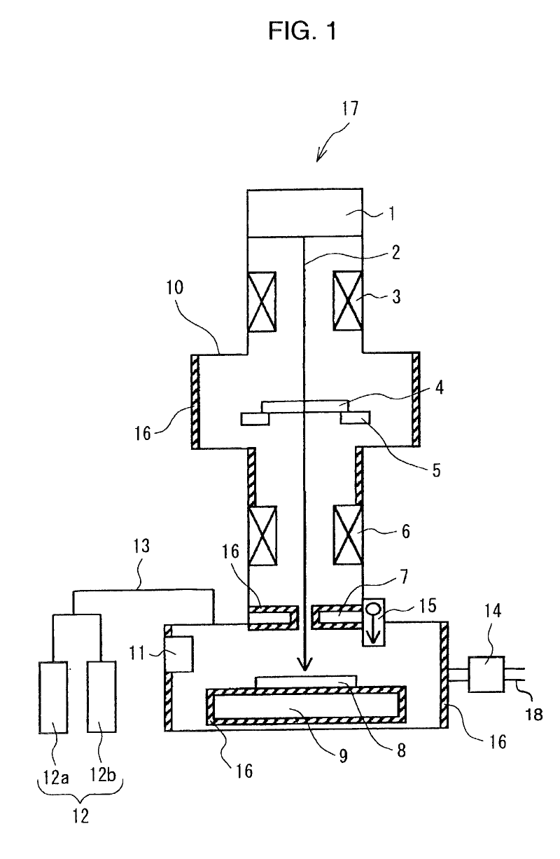

The system of FIG. 1 includes an electron gun 1 disposed in an upper part of the electron-beam microlithography system 17. The electron gun 1 generates an electron beam 2 that propagates through an illumination-optical system 3. The illumination-optical system 3 typically includes multiple condensers, deflectors, magnetic lenses, beam-forming apertures, etc. For illustrative purposes, however, the illumination-optical system 3 is shown as comprising only a single component. The illumination-optical system 3 shapes and focuses the electron beam 2 into an “illumination beam” that is directed onto a selected region, or “subfield,” of the patterned reticle 4 that is to be transferred.

The reticle 4 is mounted to a reticle chuck (not shown, but well understood in the art) provided on the upstream-facing surface of a reticle stage 5. The reticle 4 may be affixed to the reticle chuck via electrostatic adhesion or other suitable means. As the illumination beam passes through the irradiated region of the reticle 4, the beam acquires an aerial image of the illuminated region, and thus becomes a “patterned beam” propagating downstream of the reticle. The patterned beam then passes through a projection-optical system 6, which typically includes multiple condenser lenses, aberration-correction lenses, coils, deflectors, and a contrast aperture 7. For illustrative purposes, however, the projection-optical system 6 is shown as comprising only a single component.

The substrate (e.g., semiconductor wafer) 8 is mounted on a “wafer chuck” (not shown, but well understood in the art) located on an upstream-facing surface of a substrate stage 9. The substrate 8 may be affixed to the wafer chuck via electrostatic adhesion or other suitable means. The projection-optical system 6 deflects and focuses the patterned beam onto a predetermined region on the substrate 8. A detector 15, which detects an alignment mark on the substrate stage 9, is used to position the substrate 8 accurately at a predetermined position for exposure.

All the parts of the illumination-optical system 3 and the projection-optical system 6 are housed inside a vacuum chamber 10. During microlithographic exposure, the interior of the vacuum chamber 10 is maintained at a suitable vacuum.

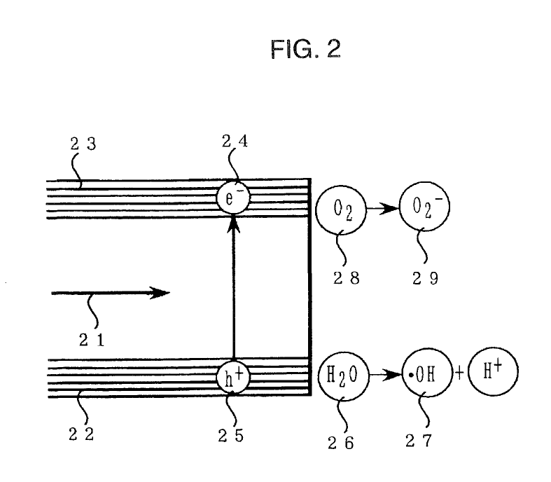

The basic principle of removing contaminant deposits from inside an electron-beam microlithography system using titanium oxide (TiO₂) is explained with reference to FIG. 2. FIG. 2 shows the energy-band structure of TiO₂, which is an exemplary photocatalytic material that reacts with and decomposes certain contaminants whenever the TiO₂ is irradiated with ultraviolet light (UV) 21. Titanium oxide is an n-type semiconductor having a band gap of about 3.2 eV, which is equivalent to radiation having a wavelength of about 380 nm. Thus, whenever radiation having a wavelength shorter than 380 nm is absorbed by titanium oxide, an electron 24 is excited from a valence band 22 to a conduction band 23, creating a hole 25 in the valance band 22. The hole 25 oxidizes a water molecule 26 inside the vacuum chamber and creates a hydroxy radical (.OH) 27. The electron 24 in the conduction band 23 also ionizes an oxygen molecule 28 and creates a superoxide ion (O₂⁻) 29. The resulting hydroxy radicals 27 and superoxide ions 29 react with and decompose hydrocarbon-type contaminants with which the radicals and superoxide ions come into contact. Thus, if water vapor or oxygen is introduced into a vacuum chamber coated with titanium oxide that is being irradiated with UV radiation, any hydrocarbon-type contaminants inside the vacuum chamber and contacted by the hydroxy radicals and superoxide ions will be decomposed to volatile reaction products.

Referring again to FIG. 1, a photocatalytic layer 16 comprising titanium oxide is formed as a film on selected regions of the surface of the inner wall of the vacuum chamber 10 and on the surface of various components inside the vacuum chamber 10 (e.g., on surfaces of the contrast aperture 7, the substrate stage 9, etc.). The photocatalytic layer 16 is not limited to a layer comprising titanium oxide, but may comprise any substance or combination of substances exhibiting the photocatalytic effect described above with reference to FIG. 2. For example, any of various photocatalysts such as zinc oxide (ZnO), cadmium sulfide (CdS), etc., may be used. Moreover, the titanium oxide in the photocatalytic layer 16 may be combined with a metal (e.g., platinum (Pt), chromium (Cr), etc.).

To irradiate the photocatalytic layer 16, a radiation source 11 is disposed inside the vacuum chamber 10 (or at least situated and configured to direct radiation into the vacuum chamber onto the photocatalytic layer 16). The radiation source 11 irradiates the inner walls of and the various components inside of the vacuum chamber 10 with, for example, ultraviolet light. The radiation source 11 may comprise any suitable light source, such as a mercury lamp, KrF excimer laser, XeCl excimer laser, nitrogen laser, etc. A gas-introduction tube 13 fluidly couples the vacuum chamber 10 with a tank 12 desirably located outside the vacuum chamber. The gas-introduction tube 13 is configured to introduce water vapor and/or oxygen into the interior of the vacuum chamber 10 from the tank 12. Individual tanks 12a, 12b may be used for introducing water vapor and oxygen, respectively, separately into the vacuum chamber 10.

During operation, the amount of contaminants adhering to the walls and components of the vacuum chamber 10 may be measured by a detector (not shown). Whenever a certain threshold contamination level is reached, microlithography normally performed using the system is halted and water vapor and/or oxygen are introduced into the interior of the vacuum chamber 10. The radiation source 11 is energized to produce radiation (e.g., ultraviolet radiation) that irradiates the inner walls and components of the vacuum chamber 10. The photocatalytic layers 16, upon receiving the radiation, convert the water vapor and oxygen into hydroxy radicals and superoxide ions that decompose the hydrocarbon-type contaminants into volatile reaction products. The reaction products are then exhausted from the vacuum chamber 10 by an exhaust pump 14 and an exhaust tube 18 fluidly coupling the interior of the vacuum chamber 10 and the exhaust pump 14 together. Thus, the contaminant deposits are removed quickly from the vacuum chamber 10 without having to disassemble the microlithography system 17. Because the microlithography system 17 can be restarted immediately after exhausting the volatile reaction products, the system described above results in an overall increase in the throughput of the system.

In an alternative embodiment of the system described above, the electron beam 2 continues to operate during irradiation of the vacuum chamber 10 by the radiation source 11. In this alternative embodiment, the electron beam 2 also converts molecules of water vapor and/or oxygen into hydroxy radicals and superoxide ions that help decompose the contaminants inside the vacuum chamber 10. Use of the electron beam 2 together with the radiation generated from the radiation source 11 increases the decomposition efficiency and shortens the time required to remove the contaminants from the vacuum chamber 10.

### FIRST WORKING EXAMPLE

The following working example is provided to exemplify certain features of the disclosed embodiments. The scope of the invention should not be limited to those features exemplified.

In this example, a contrast aperture 7 was coated with a photocatalytic layer 16 and positioned inside a vacuum chamber 10 of an electron-beam microlithography system 17. The photocatalytic layer 16 comprised a film of titanium oxide having a thickness of 2000 Angstroms. The electron-beam microlithography system 17 was operated until hydrocarbon-type contaminants had accumulated on the surface of the contrast aperture 7. These contaminants exhibited charge-up, which caused visually detectable perturbation of the trajectory of the electron beam 2. For decomposing the contaminant deposits water vapor was introduced into the vacuum chamber 10 from a tank 12 via a gas-introduction tube 13 at a pressure of 600 Pa. A mercury lamp located inside the vacuum chamber was energized, and produced UV radiation of 254 nm that irradiated the contrast aperture 7. The irradiated photocatalytic layer 16 on the contrast aperture produced superoxide ions and hydroxy radicals that reacted with the contaminants adhering to the contrast aperture 7. The reaction products were volatile and readily removed. As a result of this in situ cleaning, perturbations of the electron beam were eliminated.

### WORKING EXAMPLE 2

In this working example, an alignment mark on the substrate stage 9 was coated with a photocatalytic layer 16 and positioned inside a vacuum chamber 10 of an electron-beam microlithography system 17. The photocatalytic layer 16 comprised a film of titanium oxide having a thickness of 2000 Angstroms. The electron-beam microlithography system 17 was operated until hydrocarbon-type contaminants had accumulated on the surface of the alignment mark. The contaminant deposit on the alignment mark made it difficult for a detector 15 to detect the alignment mark, making accurate positioning impossible. To decompose the contaminant deposit, water vapor at a pressure of 400 Pa was introduced into the vacuum chamber 10 from a tank 12 via a gas-introduction tube 13. A nitrogen laser was energized, which irradiated the alignment mark with radiation having a wavelength of 337 nm. The irradiated photocatalytic layer 16 produced hydroxy radicals that reacted with the contaminant deposit adhering to the alignment mark. The volatile reaction products were removed. As a result of this in situ cleaning, the detector 15 again could perform high-precision positioning of the substrate stage 9.

Whereas the invention has been described in connection with representative embodiments and examples, the invention is not limited to those embodiments and examples. On the contrary, the invention is intended to encompass all modifications, alternatives, and equivalents as may be included within the spirit and scope of the invention, as defined by the appended claims.

What is claimed:

1. A charged-particle-beam (CPB) microlithography system, comprising:
a vacuum chamber having an inner wall;
a CPB optical system positioned within the vacuum chamber; and
a photocatalytic layer disposed on at least a portion of the inner wall of the vacuum chamber.

2. The system of claim 1, wherein the photocatalytic layer comprises a substance selected from the group consisting of titanium oxide, zinc oxide, cadmium sulfide, and mixtures thereof.

3. The system of claim 1, wherein the photocatalytic layer comprises a photocatalyst that reacts with water vapor and oxygen to create hydroxy radicals and superoxide ions, respectively.

4. The system of claim 1, further comprising a radiation source situated and configured to irradiate the photocatalytic layer.

5. The system of claim 4, wherein the radiation source is situated inside the vacuum chamber.

6. The system of claim 4, wherein the radiation source produces ultraviolet radiation.

7. The system of claim 1, further comprising:
a tank containing water vapor or oxygen; and
a gas-introduction tube in fluid communication with the tank and the interior of the vacuum chamber.

8. The system of claim 1, further comprising:
an exhaust pump; and
an exhaust tube fluidly connecting the exhaust pump with the interior of the vacuum chamber.

9. A charged-particle-beam (CPB) microlithography system, comprising:
a vacuum chamber;
a CPB source positioned at an upstream end of the vacuum chamber, the CPB source generating a charged particle beam;
an illumination-optical system positioned in the vacuum chamber and downstream of the CPB source, the illumination-optical system including multiple respective beam-shaping and beam-focusing components;
a reticle stage positioned in the vacuum chamber and downstream of the illumination-optical system, the reticle stage being configured to hold a pattern-defining reticle;
a projection-optical system positioned in the vacuum chamber and downstream of the reticle stage, the projection-optical system including multiple respective beam-shaping and beam-focusing components;
a substrate stage positioned in the vacuum chamber and downstream of the projection-optical system, the substrate stage being configured to hold a lithographic substrate; and
a photocatalytic layer disposed on a portion of the substrate stage or on at least one of the multiple beam-shaping and beam-focusing components of the illumination-optical system and projection-optical system.

10. The system of claim 9, wherein the photocatalytic layer comprises a substance selected from the group consisting of titanium oxide, zinc oxide, cadmium sulfide, and mixtures thereof.

11. The system of claim 9, wherein the photocatalytic layer reacts with water vapor and oxygen to create hydroxy radicals and superoxide ions, respectively.

12. The system of claim 9, further comprising a radiation source situated and configured to irradiate the photocatalytic layer.

13. The system of claim 12, wherein the radiation source produces ultraviolet radiation.

14. The system of claim 9, further comprising:
a tank containing water vapor or oxygen; and
a gas-introduction tube fluidly connecting the tank with the interior of the vacuum chamber.

15. The system of claim 9, further comprising:
an exhaust pump; and
an exhaust tube fluidly connecting the exhaust pump with the interior of the vacuum chamber.

16. A method for decomposing hydrocarbon-type contaminants that have accumulated in a charged-particle-beam (CPB) microlithography system, comprising:
coating at least a portion of a vacuum chamber or object therein with a photocatalytic layer, the vacuum chamber housing a CPB optical system of the CPB microlithography system;
introducing a reactant into the vacuum chamber, the reactant being formulated to produce one or more of superoxide ions and hydroxy radicals when irradiated with a radiation; and
irradiating the photocatalytic layer with the radiation, thereby causing the photocatalytic layer to react with the reactant and create one or more of hydroxy radicals and superoxide ions that decompose the contaminant deposits and produce volatile reaction products.

17. The method of claim 16, wherein the radiation is ultraviolet radiation.

18. The method of claim 16, further comprising pumping the volatile reaction products out of the vacuum chamber through an exhaust tube.

19. The method of claim 16, further comprising simultaneously irradiating the photocatalytic layer with the charged particle beam used in the CPB microlithography system.

20. The method of claim 16, wherein the reactant is selected from the group consisting of water vapor, oxygen, and mixtures thereof.

21. The method of claim 16, wherein the photocatalytic layer comprises a substance selected from the group consisting of titanium oxide. zinc oxide, cadmium sulfide, and mixtures thereof.

22. A method for decomposing deposits of a hydrocarbon-type contaminant inside a vacuum chamber of a charged-particle-beam (CPB) microlithography system, the CPB microlithography system including a substrate stage and multiple beam-shaping and beam-focusing components located inside the vacuum chamber, the method comprising:
coating at least a portion of one or more of the substrate stage, the vacuum chamber, and the beam-shaping or beam-focusing components with a photocatalytic layer;
introducing a reactant into a vacuum chamber, the reactant being formulated to produce hydroxy radicals and superoxide ions when irradiated with a radiation; and
irradiating the photocatalytic layer with a radiation sufficient to cause the photocatalytic layer to react with the reactant and create hydroxy radicals and superoxide ions that decompose the contaminants and produce volatile reaction products.

23. The method of claim 22, wherein the radiation is ultraviolet radiation.

24. The method of claim 22, further comprising pumping the volatile reaction products out of the vacuum chamber through an exhaust tube.

25. The method of claim 22, further comprising simultaneously irradiating the photocatalytic layer with the charged particle beam used in the CPB microlithography system.

26. The method of claim 22, wherein the reactant is selected from the group consisting of water vapor, oxygen, and mixtures thereof.

27. The method of claim 22, wherein the photocatalytic layer comprises a substance selected from the group consisting of titanium oxide, zinc oxide, cadmium sulfide, and mixtures thereof.
